(19) United States
(12) Patent Application Publication
(10) Pub. No.: US 2024/0387495 A1
(43) Pub. Date: Nov. 21, 2024

(54) SEMICONDUCTOR PACKAGE AND METHOD FOR MANUFACTURING THE SAME

(71) Applicant: Samsung Electronics Co., Ltd., Suwon-si (KR)

(72) Inventors: Minwoo LEE, Suwon-si (KR); Joonho JUN, Suwon-si (KR); Duk Sung KIM, Suwon-si (KR); Byoungkon JO, Suwon-si (KR)

(73) Assignee: Samsung Electronics Co., Ltd., Suwon-si (KR)

(21) Appl. No.: 18/508,143

(22) Filed: Nov. 13, 2023

(30) Foreign Application Priority Data
May 16, 2023 (KR) 10-2023-0063020

(51) Int. Cl. H01L 25/18; H01L 23/00; H01L 23/48; H01L 23/535; H01L 23/538; H01L 25/065

(52) U.S. Cl. CPC H01L 25/18; H01L 23/481; H01L 23/535; H01L 23/5386; H01L 24/13; H01L 24/16; H01L 24/17; H01L 24/48; H01L 24/49; H01L 25/0657; H01L 2224/13023; H01L 2224/16235; H01L 2224/1716; H01L 2224/48105; H01L 2224/49177; H01L 2224/4945; H01L 2225/06513; H01L 2225/06541; H01L 2225/06551

(57) ABSTRACT

A semiconductor package according to an example includes a base die having a first surface and a second surface opposite each other; a first group of core dies stacked on the first surface of the base die and electrically connected to the base die; a mount member facing the second surface of the base die; a second group of core dies between the base die and the mount member, the second group of core dies being stacked on the second surface of the base die and electrically connected to the base die; and an interface for an electrical connection between the base die and the mount member.

### CROSS-REFERENCE TO RELATED APPLICATION

This application claims priority to and the benefit of Korean Patent Application No. 10-2023-0063020 filed in the Korean Intellectual Property Office on May 16, 2023, the entire contents of which are incorporated herein by reference.

### BACKGROUND

### (a) Field

The present disclosure relates to a semiconductor package and a manufacturing method thereof. Particularly, the present disclosure is suitable for an application to high bandwidth memory (HBM) semiconductor packages.

### (b) Description of the Related Art

Modern technologies, such as an Al computing, may require computational chips with high processing speed and high-bandwidth memory. The demand for high-bandwidth memory is rapidly increasing. In response to this, a technique of vertically stacking a plurality of core dies has been proposed.

FIG. 15 is a view schematically showing a conventionally typical HBM semiconductor package. The HBM semiconductor package 1000 includes a base die 20, a first group of core dies G1 stacked on one surface of the base die 20, a processing chip 100, and an interposer 50 on which the processing chip 100 and the base die 20 are mounted.

A plurality of through silicon vias (TSVs) are formed in the first group of the core dies G1 to electrically connect each core die to the base die 20. The TSVs facilitate stacking a plurality of core dies with high density while increasing a communication speed between the dies.

The base die 20 is also referred to as a logic die or a buffer die. The base die 20 includes a physical layer (PHY) interface and a DA (Direct Access) interface. The PHY interface is a port for a communication with the processing chip 100. The base die 20 and the processing chip 100 are connected through wires in the interposer 50.

The HBM semiconductor package 1000 may include eight core dies. The number of the core dies is variable. For example, 12 core dies may be stacked, or 16 core dies may be stacked. As more core dies are stacked, the bandwidth increases, but a risk of a signal delay and manufacturing defects also increases.

When more core dies are stacked, a distance between the uppermost core die and the base die 20 increases. This causes a latency and also affects the processing speed of the processing chip 100.

In addition, if the number of the stacked core dies is large, the risk of defects due to a warpage also increases. Heat is applied whenever the core dies are stacked. The repeated heating may cause the unacceptable warpage.

For the above reasons, the number of the core dies stacked on the base die may be limited.

### SUMMARY

Embodiments of the present disclosure relate to a semiconductor package and a manufacturing method thereof in which a number of core dies stacked on a base die is increased while limiting and/or suppressing a delay and a warpage.

According to an example embodiment of the present disclosure, a semiconductor package may include a base die having a first surface and a second surface opposite each other; a first group of core dies stacked on the first surface of the base die and electrically connected to the base die; a mount member facing the second surface of the base die; a second group of core dies between the base die and the mount member, the second group of core dies being stacked on the second surface of the base die and electrically connected to the base die; and an interface for an electrical connection between the base die and the mount member.

According to an example embodiment of the present disclosure, a high-bandwidth memory (HBM) semiconductor package may include a base die having a first surface and a second surface opposite each other; a first group of core dies stacked on the first surface of the base die and electrically connected to the base die through a first through-silicon via; a mount member facing the second surface of the base die; a second group of core dies between the base die and the mount member, the second group of core dies stacked on the second surface of the base die and electrically connected to the base die through a second through-silicon via; and an interface for an electrical connection between the base die and the mount member. The base die may include a redistribution layer (RDL), a physical layer (PHY) interface and a direct access (DA) interface. An area of the base die may be larger than an area of the first group of the core dies and larger than an area of the second group of the core dies. The first surface of the base die and the second surface of the base die each may include a mounting area and a peripheral area extending in at least one direction outward of the mounting area. The first group of the core dies may be stacked on the mounting area of the first surface of the base die. The second group of the core dies may be stacked on the mounting area of the second surface of the base die. The PHY interface and the DA interface may be in a peripheral region of the base die and may be electrically connected to the mount member through the interface.

According to an example embodiment of the present disclosure, a manufacturing method may include mounting a base die on a carrier, the base die including a first surface and a second surface opposite each other, each of the first surface and the second surface including a mounting area and a peripheral area around the mounting area, and the mounting the base die on the carrier being performed so that the second surface faces upward; providing a copper pillar on the peripheral area of the second surface of the base die; stacking a second group of core dies on the mounting area of the second surface of the base die; molding the copper pillar and the second group of the core dies; separating the base die from the carrier and turning the base die over so that the first surface of the base die faces upward; stacking a first group of core dies on the mounting area of the first surface; and electrically connecting an other end of the copper pillar to the connection pad on the interposer.

According to example embodiments of the present disclosure, since the core dies are stacked on both surfaces of the base die, the structural stability is high and an occurrence of a warpage is limited and/or suppressed compared to a case where core dies are stacked on one surface.

According to example embodiments of the present disclosure, when the core dies are stacked on both surfaces of the base die and fewer core dies are stacked on the mounting member side, a delay is reduced compared to the case where core dies are stacked on one surface.

### BRIEF DESCRIPTION OF THE DRAWINGS

FIG. 1 is a cross-sectional view showing a schematic structure of a semiconductor package according to an example embodiment of the present disclosure.

FIG. 2 is a cross-sectional view showing a schematic structure of a semiconductor package according to another example embodiment of the present disclosure.

FIG. 3 is a cross-sectional view showing a schematic structure of a semiconductor package according to another example embodiment of the present disclosure.

FIG. 4 is a cross-sectional view showing a schematic structure of a semiconductor package according to another example embodiment of the present disclosure.

FIG. 5 is a cross-sectional view showing a schematic structure of a semiconductor package including a processing chip according to an example embodiment of the present disclosure.

FIG. 6 is a cross-sectional view showing a schematic structure of a semiconductor package including a processing chip according to another example embodiment of the present disclosure.

FIG. 7 is a cross-sectional view showing a schematic structure of a semiconductor package including a processing chip according to another example embodiment of the present disclosure.

FIG. 8 is a cross-sectional view showing a schematic structure of a semiconductor package including a processing chip according to another example embodiment of the present disclosure.

FIG. 9 is a cross-sectional view showing a schematic structure of a semiconductor package including a processing chip according to another example embodiment of the present disclosure.

FIG. 10 is a cross-sectional view showing a schematic structure of a semiconductor package including a processing chip according to another example embodiment of the present disclosure.

FIG. 11 is a top plan view showing a schematic structure of a semiconductor package including a processing chip according to an example embodiment of the present disclosure.

FIG. 12 is a top plan view showing a schematic structure of a semiconductor package including a processing chip according to another example embodiment of the present disclosure.

FIG. 13 is a top plan view showing a schematic structure of a semiconductor package including a processing chip according to another example embodiment of the present disclosure.

FIG. 14A to FIG. 14G are views showing a manufacturing method of a semiconductor package according to an example embodiment of the present disclosure.

FIG. 15 is a cross-sectional view of a schematic structure of a conventional high-bandwidth memory semiconductor package.

### DETAILED DESCRIPTION

Example embodiments will be described more fully hereinafter with reference to the accompanying drawings, in which embodiments of inventive concepts are shown. As those skilled in the art would realize, the described embodiments may be modified in various different ways, all without departing from the spirit or scope of inventive concepts.

In order to clarify aspects of inventive concepts, parts that are not connected with the description will be omitted, and the same elements or equivalents are referred to by the same reference numerals throughout the specification.

Further, since sizes and thicknesses of constituent members shown in the accompanying drawings are arbitrarily given for better understanding and ease of description, embodiments of inventive concepts are not limited to the illustrated sizes and thicknesses. In the drawings, the thickness of layers, films, panels, areas, etc., are exaggerated for clarity. In the drawings, for better understanding and ease of description, thicknesses of some layers and areas are excessively displayed.

It will be understood that when an element such as a layer, film, area, or substrate is referred to as being “on” another element, it can be directly on the other element or intervening elements also may be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise”, and variations such as “comprises” or “comprising”, will be understood to imply the inclusion of stated elements but not the exclusion of any other elements.

Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Further, in the specification, the phrase “on a plane” means when an object portion is viewed from above, and the phrase “on a cross-section” means when a cross-section taken by vertically cutting an object portion is viewed from the side.

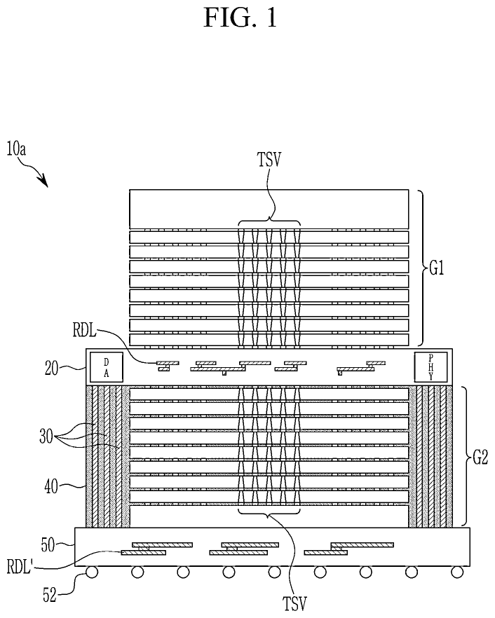

FIG. 1 is a cross-sectional view of a schematic structure of a semiconductor package according to an example embodiment of the present disclosure.

A semiconductor package 10a includes a base die 20 having a first surface and a second surface, a first group of core dies G1 stacked on the first surface, a second group of core dies G2 stacked on the second surface, an interposer 50, and a plurality of copper pillars (Cu Pillar) 30 providing an electrical connection between the base die 20 and the interposer 50.

The base die 20 is also referred to as a logic die or a buffer die when the core dies are memory dies. On the first surface (the surface facing upward in FIG. 1) of the base die 20, eight core dies are stacked, thereby forming the first group of the core dies G1. Eight core dies are also stacked on the second surface (the surface facing downward in FIG. 1) of the base die 20, thereby forming the second group of the core dies G2.

The number of the first group of the core dies G2 is not limited to eight. 4, 12, 16 or more core dies may be stacked to form the first group of the core dies G1. Similarly, the number of the second group of the core dies G2 is not limited to eight. 4, 12, 16 or more core dies may be stacked to form the second group of the core dies G2.

In some example embodiments, the core die may be a DRAM semiconductor die. Each core die includes a bank area for storing a data and an input and output (I/O) area for an input and output of a data. The input and output area includes a plurality of through-silicon vias TSVs. Except for the uppermost core die, each of the remaining stacked core dies is electrically connected to the base die 20 through a plurality of through-silicon vias TSVs. Although not shown, the base die 20 may also include a plurality of through-silicon vias TSVs connected to the through-silicon vias TSVs of the first group of the core dies G1 and the through-silicon vias TSVs of the second group of the core dies G2. The stacked core dies may be electrically connected to each other by a micro bump array or electrically connected to each other by a hybrid bonding, and the electrical connection between the stacked core dies may be implemented by various methods.

The base die 20 may include a redistribution layer RDL, a physical layer (PHY) interface, and a Direct Access (DA) interface. The redistribution layer RDL is a structure that configures wires to connect the first group of the core dies G1 and the second group of the core dies G2 to external devices. The PHY interface provides a signal path so that the first group of the core dies G1 and the second group of the core dies G2 may communicate a data with external devices (e.g., processing chips). The DA interface provides a signal path for a test of the base die 20. Although not shown, the base die 20 may further include a part of a power network, which is for supplying a power supplied from the outside to each core die. The power network may include a decoupling capacitor.

The base die 20 has a larger area than the core die. The base die 20 includes connection pads for the electrical connection with external devices. The PHY interface and the DA interface may include these connection pads. Since the core dies are stacked on the first and second surfaces of the base die 20, these connection pads are disposed along the edges of the base die 20. As shown in FIG. 1, the first surface and second surface of the base die 20 are wider than the core dies. The PHY interface and the DA interface are disposed along the edge of the base die 20. The power may be supplied from the outside to he first group of the core dies G1 and the second group of the core dies G2 through the connection pads disposed to the edge of the base die 20.

In some example embodiments, the base die 20 may further include a buffer circuit. The buffer circuit facilitates a data input and output for the plurality of stacked core dies.

In some example embodiments, the base die 20 may further include a processing circuit. According to the present example embodiment, since the base die 20 has the larger area than the core die, and the PHY interface and the DA interface are disposed on the edge, it has a relatively larger space than the base die having the same area as the core die. In order to utilize the relatively large space, the base die 20 according to the present example embodiment may further include a processing circuit. The processing circuit may be configured to process the data input/output from/to the core dies.

The interposer 50 faces the base die 20 via the second group of the core dies G2 interposed therebetween. The interposer 50 may include a redistribution layer RDL′ and may include a bump array 52 to be electrically connected to another device or a substrate. The interposer 50 is just one example of a mount member. In order for the base die 20 to be connected to an external device through an interface such as a copper pillar 30, a combination of the base die 20 and the core dies G1 and G2 needs to be mounted on a mount member. The mount member includes a connection pad electrically connected to the copper pillar 30, and is a medium that communicates a power and signals with the base die 20. In the present example embodiment and the following example embodiments, the interposer 50 is disclosed as a mount member. However, the present disclosure is not limited to the interposer.

In the present example embodiment, as an interface for an electrical connection between the base die 20 and the interposer 50, a plurality of copper pillars 30 are provided. One end of each copper pillar 30 is connected to a connection pad provided on the edge of the second surface of the base die 20, and the other end thereof is connected to a connection pad provided on the interposer 50. A mold material 40 is molded for an insulation and a protection. Although not shown, an insulating material is also filled in a gap between the first group of the core dies G1.

In some example embodiments, the height of the first group of the core dies G1 including eight core dies may be about 700 μm. The height may vary according to the number of the stacked core dies. If the number of the second group of the core dies G2 is equal to the number of the first group of the core dies G2, the heights thereof are also approximately equal. The base die 20 may have a thickness suitable for functioning as a reinforcing material to maintain the strength of the entire package 10a. In an example embodiment, the thickness of the base die 20 may be 50 to 130 μm. The base die 20 may have a thickness suitable for limiting and/or suppressing a phenomenon such as a warpage caused by heat applied during the stacking process of the first group of the core dies G1 and the second group of the core dies G2.

When using the semiconductor package 10a according to the present example embodiment, since a plurality of core dies are stacked on both surfaces of the base die 20, a high-bandwidth memory semiconductor package having a stable structure may be obtained.

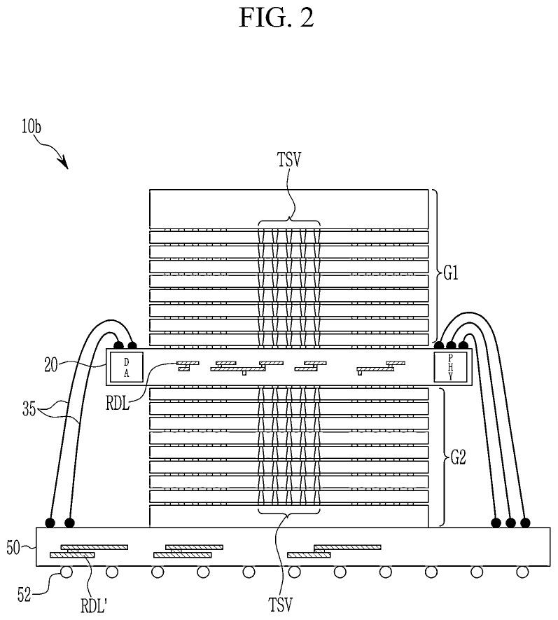

FIG. 2 is a cross-sectional view showing a schematic structure of a semiconductor package according to another example embodiment of the present disclosure.

A semiconductor package 10b includes a base die 20 having a first surface and a second surface, a first group of core dies G1 stacked on the first surface, a second group of core dies G2 stacked on the second surface, an interposer 50, and a plurality of wires 35 providing an electrical connection between the base die 20 and the interposer 50.

Since the description of the semiconductor package 10a may be referred for other constituent elements except for using the wire 35 for the electrical connection between the base die 20 and the interposer 50, a repeated description is omitted here.

An electrical connection is implemented between the base die 20 and the interposer 50 by a wire bonding. One end of the plurality of wires 35 is connected to a plurality of connection pads provided on the edge of the first surface of the base die 20, and the other end of the plurality of wires 35 is connected to a plurality of connection pads provided on the interposer 50. Since the wire bonding is already a well-known technique, a detailed description thereof is omitted here.

Although not shown, the entire semiconductor package 10b may be molded for a protection from an external impact and contamination.

The wire bonding is a simpler process and cheaper than the copper pillar, but uses a relatively larger space and a lower connection density than the copper pillar.

When the semiconductor package 10b according to the present example embodiment is used, since a plurality of core dies are stacked on both surfaces of the base die 20, a high-bandwidth memory semiconductor package having a stable structure is obtained.

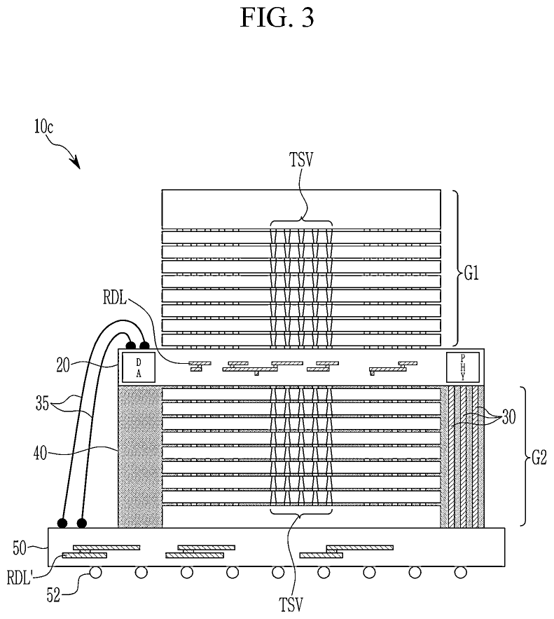

FIG. 3 is a cross-sectional view showing a schematic structure of a semiconductor package according to another example embodiment of the present disclosure.

A semiconductor package 10c includes a base die 20 having a first surface and a second surface, a first group of core dies G1 stacked on the first surface, a second group of core dies G2 stacked on the second surface, an interposer 50, and a plurality of copper pillar 30 and a plurality of wire 35 of providing an electrical connection between the base die 20 and the interposer 50.

Since the description of the semiconductor package 10a may be referred to for other constituent elements except for the copper pillar 30 and the wire 35 used for the electrical connection between the base die 20 and the interposer 50, the repeated descriptions are omitted here.

In the present example embodiment, the copper pillar 30 and the wire 35 are used together for the electrical connection between the base die 20 and the interposer 50. In FIG. 3, the copper pillar 30 and the second group of the core dies G2 are molded by a mold material 40. However, the entire semiconductor package 10c may be molded to include the wire 35, which is not limited thereto.

Although not limited thereto, the copper pillar 30 may be used for the PHY interface and the wire 35 may be used for the DA interface and/or the power network. Since the PHY interface provides a signal path, the copper pillar 30 may be used to limit and/or minimize a delay.

When the semiconductor package 10c according to the present example embodiment is used, since a plurality of core dies are stacked on both surfaces of the base die 20, a high-bandwidth memory semiconductor package having a stable structure is obtained.

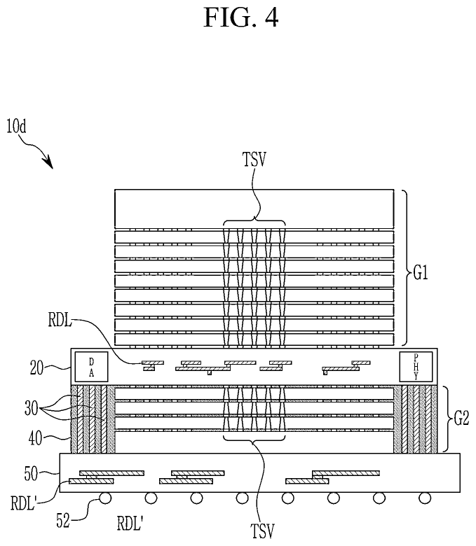

FIG. 4 is a cross-sectional view showing a schematic structure of a semiconductor package according to another example embodiment of the present disclosure.

A semiconductor package 10d includes a base die 20 having a first and second surfaces, a first group of core dies G1 stacked on the first surface, a second group of core dies G2 stacked on the second surface, an interposer 50, and a plurality of copper pillars 30 providing an electrical connection between the base die 20 and the interposer 50.

The number of the first group of the core dies G1 stacked on the first surface of the base die 20 is different from the number of the second group of the core dies G2 stacked on the second surface of the base die 20.

In the present example embodiment, while the number of the first group of the core dies G2 is 8, the number of the second group of the core dies G2 is 4. Since the number of the second group of the core dies G2 is less than the number of the first group of the core dies G2, compared to the semiconductor package 10a shown in FIG. 1, the semiconductor package 10d has the shorter copper pillar 30. The shorter copper pillar 30 has lower delay.

The number of the first group of the core dies G1 and the number of the second group of the core dies G2 are not limited to the present example embodiment. For example, the number of the first group of the core dies G2 may be 12, and the number of the second group of the core dies G2 may be 8. The number of the first group of the core dies G1 may be 12, and the number of the second group of the core dies G2 may be 4.

Alternatively, the number of the second group of the core dies G2 may be greater than the number of the first group of the core dies G1. However, as described above, in this case, the length of the copper pillar 30 is relatively long, which results in a long signal path.

In the present example embodiment, the copper pillar 30 is used as an interface for the electrical connection between the base die 20 and the interposer 50, but as in the example embodiment shown in FIG. 2 and FIG. 3, only the wire 35 may be used as an interface, or both the wire 35 and the copper pillar 30 may be used as interfaces.

In the example embodiment shown in FIG. 2 and FIG. 3, the length of the wire 35 and the copper pillar 30 may be shortened by forming the number of the second group of the core dies G2 smaller than the number of the first group of the core dies G2.

When the semiconductor package 10d according to the present example embodiment is used, since a plurality of core dies are stacked on both surfaces of the base die 20, a high-bandwidth memory semiconductor package having a stable structure is obtained.

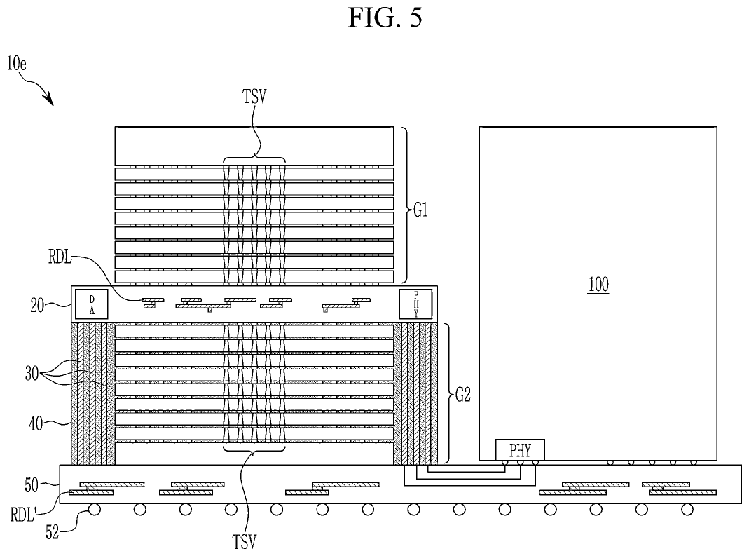

FIG. 5 is a cross-sectional view showing a schematic structure of a semiconductor package including a processing chip according to an example embodiment of the present disclosure.

A semiconductor package 10e, in addition to the constituent elements of the semiconductor package 10a shown in FIG. 1, a processing chip 100 is further included. The processing chip 100 is mounted on the interposer 50.

The processing chip 100 may be a CPU, GPU, or APU. The processing chip 100 stores a data in the core dies or draws out a data from the core dies. The processing chip 100 is connected to each core die via the base die 20. The PHY interface of the processing chip 100 is electrically connected to the PHY interface of the base die 20 through the wire circuit and the copper pillar 30 in the interposer 50.

Although not shown, the DA interface of the base die 20 may be connected to the interposer 50 through the copper pillar 30 and electrically connected to an external device through the redistribution layer of the interposer 50 and the bump array 52.

The semiconductor package 10e is a package in which a high-bandwidth memory and a processing chip 100 are mounted on one interposer 50. FIG. 5 shows one high-bandwidth memory, but a person of an ordinary skill in the art will easily understand that it is also possible to dispose a plurality of high-bandwidth memories with the same structure around the processing chip 100.

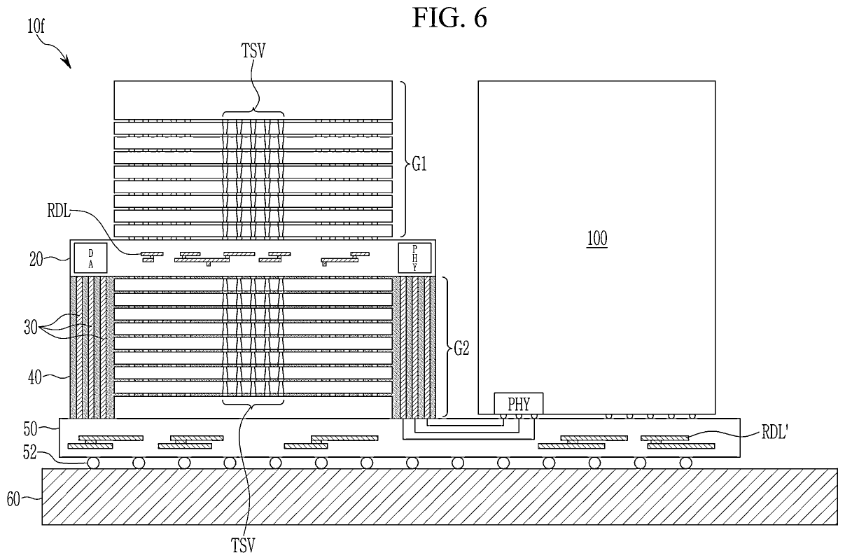

FIG. 6 is a cross-sectional view showing a schematic structure of a semiconductor package including a processing chip according to another example embodiment of the present disclosure.

The semiconductor package 10f is obtained by mounting the semiconductor package 10e shown in FIG. 5 on the substrate 60. In addition to the substrate 60, other constituent elements are listed the same as the semiconductor package 10e shown in FIG. 5, a repetitive description is omitted.

Through a reflow process, the bump array 52 of the interposer 50 is bonded to the connection pad on the substrate 60. In the reflow process, warpage of the core dies stacked on both surface of the base die 20 is relatively limited and/or suppressed.

For a simplicity of an explanation, in FIG. 6, the interposer 50 in which one high-bandwidth memory and one processing chip 100 are mounted is mounted on the substrate 60, but other devices or an additional high-bandwidth memory and a processing chip may be mounted on the substrate 60.

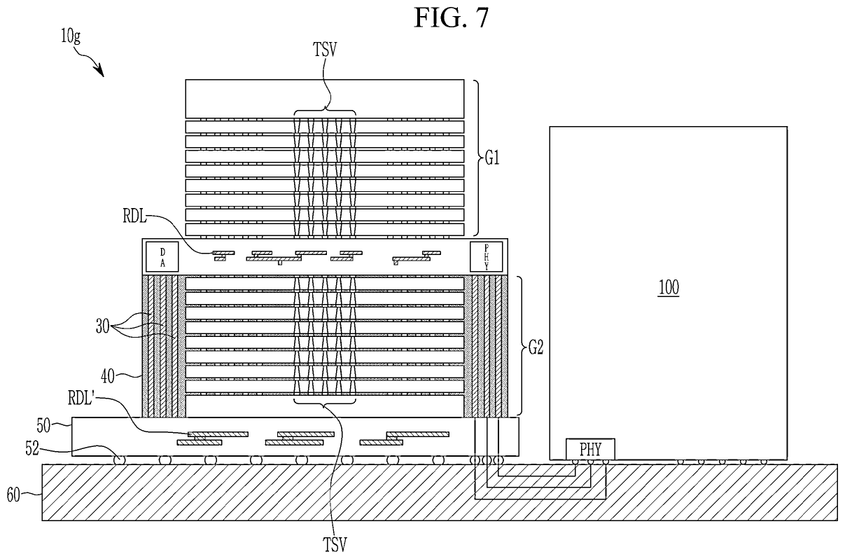

FIG. 7 is a cross-sectional view showing a schematic structure of a semiconductor package including a processing chip according to another example embodiment of the present disclosure.

For simplicity of explanation, only differences from the semiconductor package 10f of FIG. 6 are explained.

The semiconductor package 10g includes a processing chip 100 directly mounted on the substrate 60. On the interposer 50, a base die on which core dies are stacked on both surfaces is mounted. The PHY interface of the processing chip 100 is connected to the PHY interface of the base die 20 through a wire circuit of the substrate 60, a wire circuit of the interposer 50, and a copper pillar 30.

The DA interface may be connected to an external device through the copper pillar 30, the wire circuit of the interposer 50, and the wire circuit of the substrate 60. Although not shown, in an example embodiment, a bump array may be disposed on the bottom surface of the substrate 60.

In the semiconductor package 10g, compared to the semiconductor package 10f, the distance between the PHY interface of the processing chip 100 and the PHY interface of the base die 20 may be relatively long, but the arrangement of the processing chip 100 and the high-bandwidth memory may be freely designed.

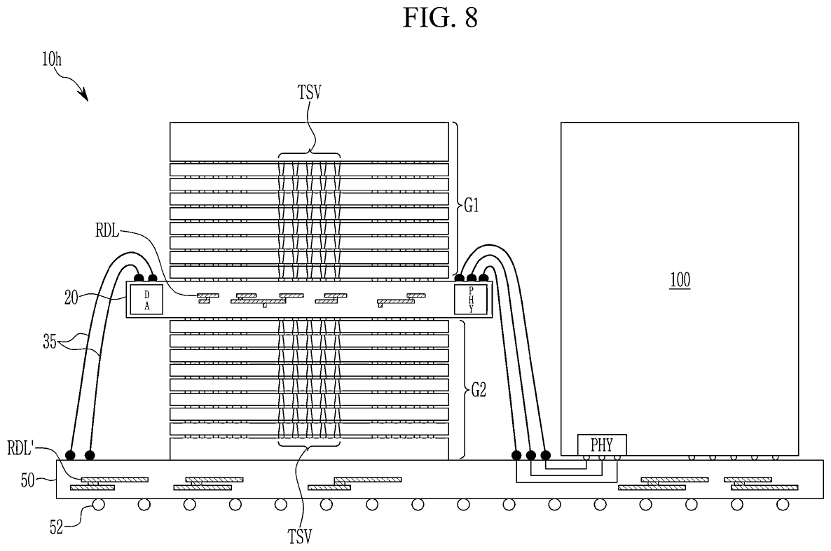

FIG. 8 is a cross-sectional view showing a schematic structure of a semiconductor package including a processing chip according to another example embodiment of the present disclosure.

In the semiconductor package 10h, compared to the semiconductor package 10e shown in FIG. 5, there is a difference in that a wire 35 is used as an interface for the electrical connection between the base die 20 and the interposer 50.

Since the constituent elements except for using the wire 35 as an interface are the same as the semiconductor package 10e, a repeated explanation is omitted here.

Similarly, in the example embodiment shown in FIG. 6 and FIG. 7, a person of an ordinary skill in the art will understand that another example variation is obtained by replacing the copper pillar 30 with the wire 35 as the interface.

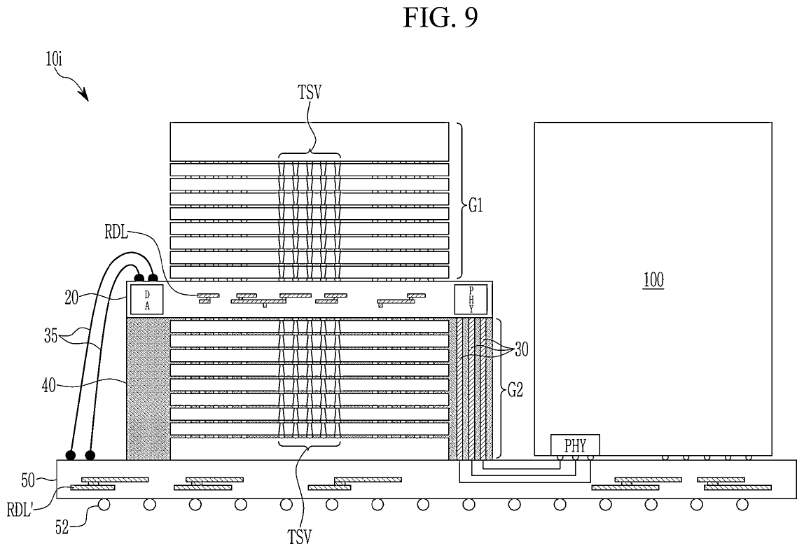

FIG. 9 is a cross-sectional view showing a schematic structure of a semiconductor package including a processing chip according to another example embodiment of the present disclosure.

In the semiconductor package 10i, compared to the semiconductor package 10e shown in FIG. 5, there is a difference in that a wire 35 and a copper pillar 30 are used together as an interface for the electrical connection between the base die 20 and the interposer 50.

Since the constituent elements except for using the wire 35 and the copper pillar 30 as an interface are the same as the semiconductor package 10e, a repeated explanation is omitted here.

Similarly, in the example embodiment shown in FIG. 6 and FIG. 7, a person of an ordinary skill in the art will understand that another example variation is obtained by replacing the copper pillar 30 with the wire 35 as the interface.

The copper pillar 30 may be used to connect the PHY interface of the base die 20 to the interposer 50. By disposing the processing chip 100 closely, the signal path may be limited and/or minimized.

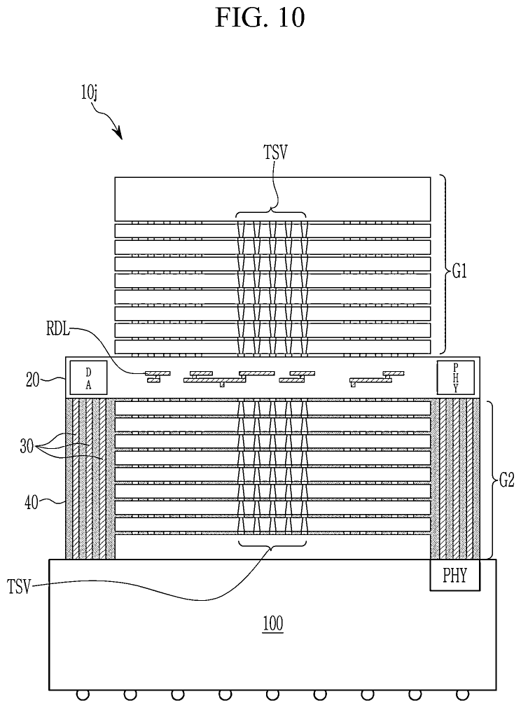

FIG. 10 is a cross-sectional view showing a schematic structure of a semiconductor package including a processing chip according to another example embodiment of the present disclosure.

The semiconductor package 10j, compared to the semiconductor package 10e shown in FIG. 5, it is different in that it does not include an interposer.

The semiconductor package 10j includes a high-bandwidth memory directly mounted on one surface of the processing chip 100. That is, the processing chip 100 is a mount member.

The PHY interface disposed on one surface of the processing chip 100 may be connected to the PHY interface of the base die 20 through the copper pillar 30. In this case, one surface of the processing chip 100 may have an area at least larger than that of the base die 20.

Although not shown, the DA interface of the base die 20 may be connected to an external device through a wire circuit provided in the processing chip 100 through the copper pillar 30.

The semiconductor package 10j uses a copper pillar 30 as an interface, but a person of an ordinary skill in the art will easily understand that it is possible to use only a wire or a combination of a wire and a copper pillar as an interface.

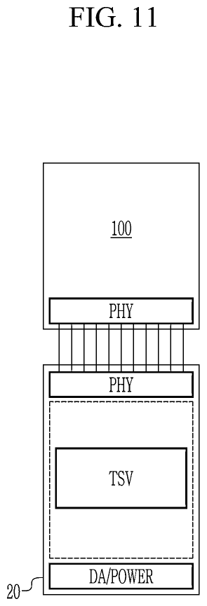

FIG. 11 is a top plan view showing a schematic structure of a semiconductor package including a processing chip according to an example embodiment of the present disclosure.

The present example embodiment may be applied to the semiconductor packages shown in FIG. 5 to FIG. 10.

The base die 20 includes peripheral areas extending to both sides of a core die mounting area (indicated by a dotted line quadrangle) including a through-silicon via TSV. A PHY interface and a DA interface/power network are respectively disposed in the peripheral area on both sides. A processing chip 100 is disposed close to the peripheral area where the PHY interface is disposed.

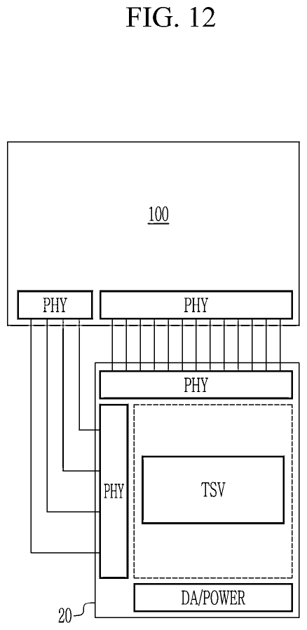

FIG. 12 is a top plan view showing a schematic structure of a semiconductor package including a processing chip according to another example embodiment of the present disclosure.

More signal paths may be required between the high-bandwidth memory and the processing chip 100. In this case, as shown in FIG. 12, the base die 20 includes the peripheral area on three sides of the mounting area, and the PHY interface may be disposed in the peripheral area of two sides among them.

The PHY interface disposed in the peripheral area of two sides may be connected to the PHY interface of the processing chip 100 through a wire circuit of the interposer, for example.

The present example embodiment also may be applied to the semiconductor packages shown in FIG. 5 to FIG. 10.

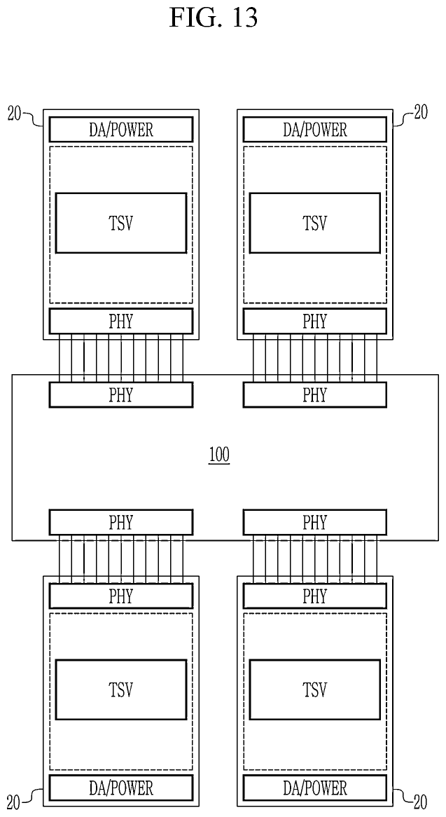

FIG. 13 is a top plan view showing a schematic structure of a semiconductor package including a processing chip, according to another example embodiment of the present disclosure.

In the present example embodiment, four base dies 20 in which the core dies are stacked on both sides are disposed around one processing chip 100. The PHY interface of each base die 20 is connected to the PHY interface of the processing chip 100, respectively.

The connection structure of each base die 20 and processing chip 100 may be applied to the semiconductor packages shown in FIG. 5 to FIG. 10.

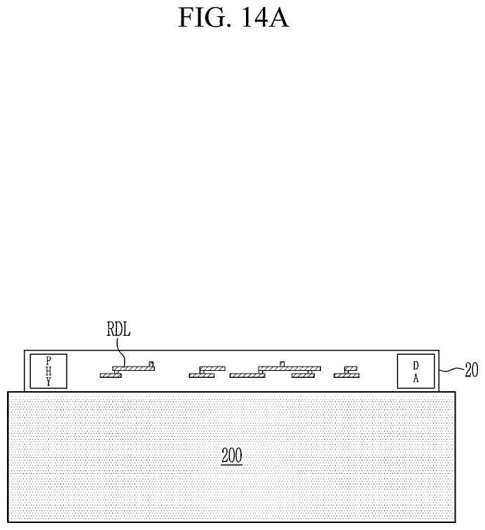

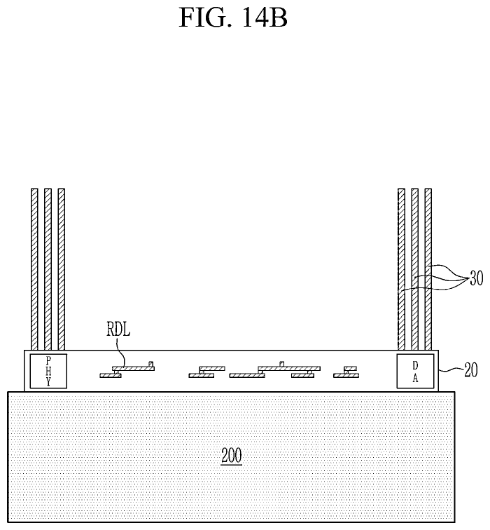

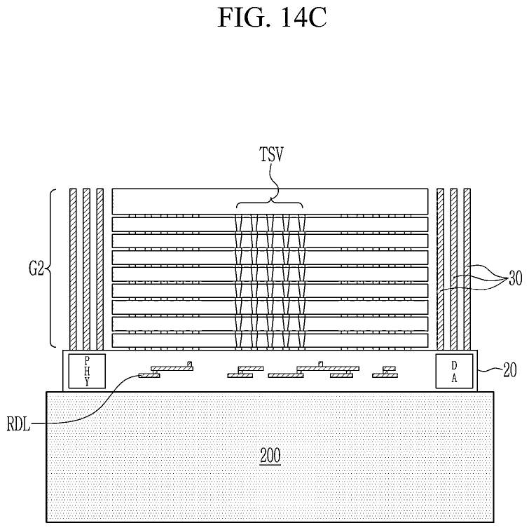

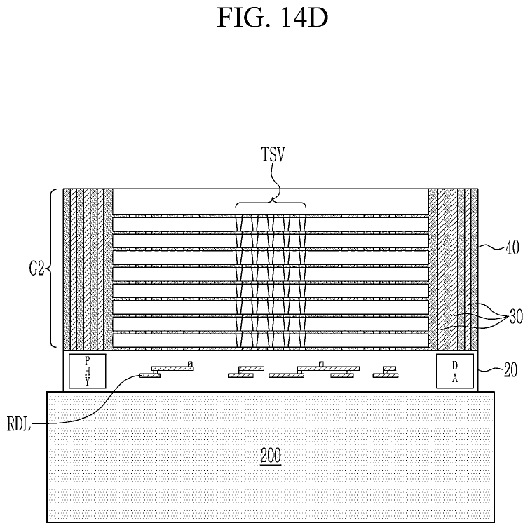

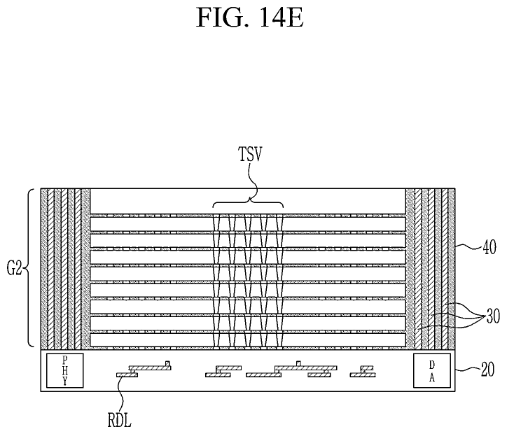

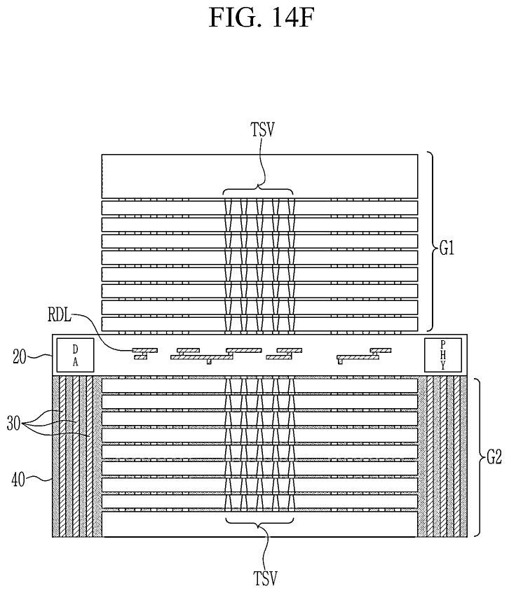

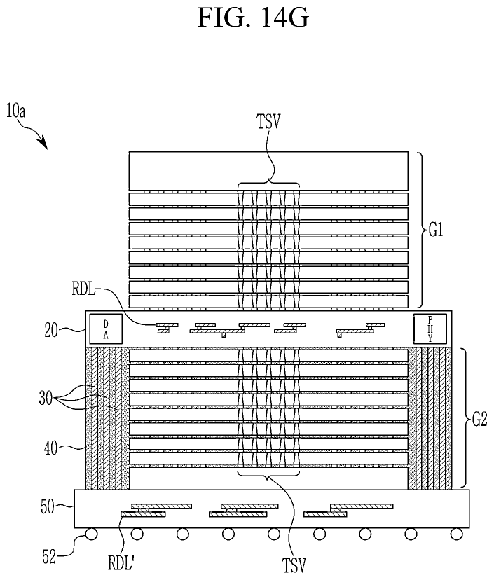

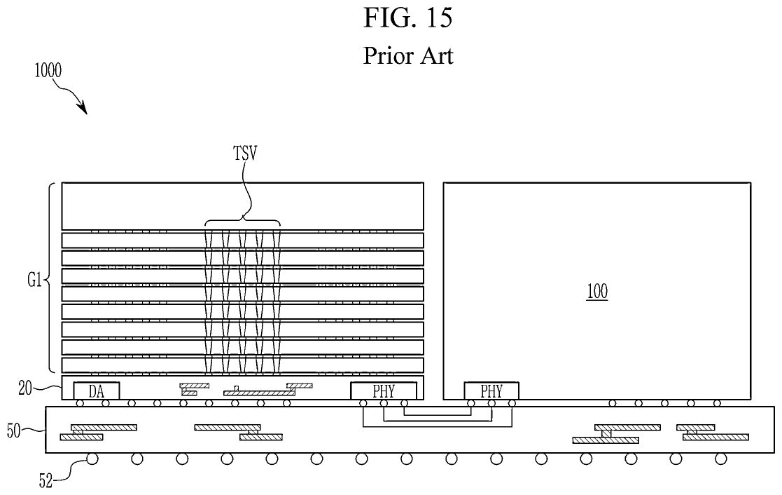

FIG. 14A to FIG. 14G are views showing a manufacturing method of a semiconductor package according to an example embodiment of the present disclosure.

The present example embodiment shows a method for manufacturing the semiconductor package 10a shown in FIG. 1. However, a person of an ordinary skill in the art may easily infer the manufacturing method of the semiconductor package shown FIG. 2 to FIG. 10 from the manufacturing method according to the present example embodiment.

In a first operation, as shown in FIG. 14A, the base die 20 is attached to the carrier 200.

The second surface of the base die 20 is attached to the carrier 200 so as to face upward. The second surface includes a mounting area on which a core die is mounted and a peripheral area extending to at least two sidewalls of the mounting area, on the peripheral area, and includes a plurality of connection pads electrically connected to copper pillars in a subsequent process.

The base die 20 includes a redistribution layer, a PHY interface and a DA interface, and may include a processing circuit. The first surface of the base die 20 and the second surface opposite to the first surface include a plurality of connection pads. These connection pads are electrically connected to the core die. The base die 20 may further include a part of a power network for supplying power from the outside to core dies.

In a second operation, as shown in FIG. 14B, a copper pillar 30 is provided in the peripheral area on the second surface of the base die 20.

The copper pillar 30 is electrically connected to the PHY interface and the DA interface for example. The height of the copper pillar 30 corresponds to the height of the second group of the core dies stacked on the second surface of the base die 20. When the number of the core dies in the second group is 8, the height of the copper pillar 30 is approximately 700 μm.

In the case of using a wire other than the copper pillar 30, a plurality of connection pads are provided in the peripheral area of the first surface of the base die 20, and the second operation is skipped.

In a third operation, as shown in FIG. 14C, the second group of the core dies G2 are stacked on the mounting area of the base die 20.

Each core die is electrically connected to the base die 20 through the through-silicon via TSV. In addition to the through-silicon via TSV, each core die may have an electrical connection with each other through micro bumps.

To stack the second group of the core dies G2, for example, a chip-on-wafer (CoW) technology may be used.

In a fourth operation, as shown in FIG. 14D, the copper pillar 30 and the second group of the core dies G2 are molded by a mold material 40.

The molding may realize an insulation and a structural stability between elements and protect elements from an external impact and contamination.

In a fifth operation, as shown in FIG. 14E, the carrier 200 is separated from the base die 20.

In a sixth operation, as shown in FIG. 14F, the base die 20 is flipped, and the first group of the core dies G1 are stacked on the first surface.

The first group of the core dies G1 are electrically connected to the base die 20 through the through-silicon via TSV. In addition to the through-silicon via TSV, each core die may have an electrical connection with each other through micro bumps.

To stack the first group of the core dies G1, for example a chip-on-wafer (CoW) technology may be used.

Although not clearly shown, an insulating material may be filled in each gap between the first group of the core dies. The insulating material achieves an electrical insulation and provides a junction force between the core dies.

In a seventh operation, as shown in FIG. 14G, the package manufactured in the sixth operation is mounted on the interposer 50, and the copper pillar 30 is electrically connected to the connection pad on the interposer 50.

Although the interposer 50 is disclosed in the present example embodiment, a substrate and a processing chip may be used as a mount member.

When using the wire 35 instead of the copper pillar 30, the second is omitted, after the seventh operation, an operation of connecting the connection pad on the interposer 50 and the connection pad on the peripheral area of the first surface of the base die 20 with a wire by a wire bonding may be added.

When using all the copper pillar 30 and the wire 35, the second operation is not omitted, after the seventh operation, an operation of connecting the connection pad on the interposer 50 and the connection pad on the peripheral area of the first surface of the base die 20 by a wire bonding is added. In this case, connection pads corresponding to the peripheral areas of both the first surface and the second surface are provided.

To manufacture the semiconductor packages shown in FIG. 5 to FIG. 9,

In addition to the above operations, an operation of mounting the substrate 60 and the processing chip 100 may be additionally performed. A detailed process is omitted because it may be sufficiently derived from the above information if it is a person of an ordinary skill in the art.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A semiconductor package comprising:
a base die having a first surface and a second surface opposite each other;
a first group of core dies stacked on the first surface of the base die and electrically connected to the base die;
a mount member facing the second surface of the base die;
a second group of core dies between the base die and the mount member, the second group of core dies being stacked on the second surface of the base die and electrically connected to the base die; and
an interface for an electrical connection between the base die and the mount member.

2. The semiconductor package of claim 1, wherein:
an area of the base die is larger an area of the first group of the core dies and larger than an area of the second group of the core dies.

3. The semiconductor package of claim 2, wherein:
the first surface of the base die and the second surface of the base die each include a mounting area and a peripheral area extending in at least one direction outward from the mounting area,
the first group of the core dies are stacked on the mounting area of the first surface of the base die,
the second group of the core dies are stacked on mounting area of the second surface of the base die, and
the interface provides an electric connection between the peripheral area of the first surface or the second surface of the base die and the mount member.

4. The semiconductor package of claim 3, wherein
the interface includes at least one of a copper pillar and a wire.

5. The semiconductor package of claim 4, wherein
the interface includes the copper pillar, and
the copper pillar provides an electric connection between the peripheral area of the second surface of the base die and the mount member.

6. The semiconductor package of claim 4, wherein
the interface includes the wire, and
the wire provides an electrical connection between the peripheral area of the first surface of the base die and the mount member.

7. The semiconductor package of claim 4, wherein
the interface includes the copper pillar and the wire,
the copper pillar provides an electrical connection between the peripheral area of the second surface of the base die and the mount member, and
the wire provides an electrical connection between the peripheral area of the first surface of the base die and the mount member.

8. The semiconductor package of claim 7, wherein:
the copper pillar is configured to provide a signal transmission path, and
the wire is configured to provide a power supply path.

9. The semiconductor package of claim 1, further comprising:
a processing chip, wherein
the mount member is an interposer,
the processing chip is on the interposer, and
the interface provides an electrical connection for signal transmission between the processing chip and first group of the core dies and signal transmission between the processing chip and the second group of the core dies.

10. The semiconductor package of claim 1, wherein:
the mount member is a processing chip, and
the interface provides an electrical connection for signal transmission between the processing chip and the first group of the core dies and signal transmission between the processing chip and the second group of the core dies.

11. The semiconductor package of claim 1, wherein:
a number of the first group of the core dies equals a number of the second group of the core dies.

12. The semiconductor package of claim 1, wherein
a number of the first group of the core dies is different than a number of the second group of the core dies.

13. The semiconductor package of claim 12, wherein
the number of the first group of the core dies is greater than the number of the second group of the core dies.

14. A high-bandwidth memory semiconductor package comprising:
a base die having a first surface and a second surface opposite each other;
a first group of core dies stacked on the first surface of the base die and electrically connected to the base die through a first through-silicon via;
a mount member facing the second surface of the base die;
a second group of core dies between the base die and the mount member, the second group of core dies stacked on the second surface of the base die and electrically connected to the base die through a second through-silicon via; and
an interface for an electrical connection between the base die and the mount member, wherein
the base die includes a redistribution layer (RDL), a physical layer (PHY) interface, and a direct access (DA) interface,
an area of the base die is larger than an area of the first group of the core dies and larger than an area of the second group of the core dies,
the first surface of the base die and the second surface of the base die each include a mounting area and a peripheral area extending in at least one direction outward of the mounting area,
the first group of the core dies are stacked on the mounting area of the first surface of the base die,
the second group of the core dies are stacked on the mounting area of the second surface of the base die, and
the PHY interface and the DA interface are in a peripheral region of the base die and electrically connected to the mount member through the interface.

15. The high-bandwidth memory semiconductor package of claim 14, wherein
the base die further includes a processing circuit.

16. The high-bandwidth memory semiconductor package of claim 14, wherein
the interface includes at least one of
a copper pillar between the peripheral area of the second surface of the base die and the mount member, or
a wire between the peripheral area of the first surface of the base die and the mount member.

17. The high-bandwidth memory semiconductor package of claim 14, wherein
a number of the second group of the core dies is less than or equal to a number of the first group of the core dies.

18. The high-bandwidth memory semiconductor package of claim 14, wherein
a thickness of the base die is 50 μm to 130 μm.

19. A manufacturing method of a semiconductor package comprising:
mounting a base die on a carrier, the base die including a first surface and a second surface opposite each other, each of the first surface and the second surface including a mounting area and a peripheral area around the mounting area, and the mounting the base die on the carrier being performed so that the second surface faces upward;
providing a copper pillar on the peripheral area of the second surface of the base die;
stacking a second group of core dies on the mounting area of the second surface of the base die;
molding the copper pillar and the second group of the core dies;
separating the base die from the carrier and turning the base die over so that the first surface of the base die faces upward;
stacking a first group of core dies on the mounting area of the first surface; and
electrically connecting an other end of the copper pillar to a connection pad on the interposer.

20. The manufacturing method of the semiconductor package of claim 19, further comprising:
electrically connecting a connection pad on the peripheral area of the first surface and a connection pad on the interposer by a wire.
